(19) United States
(12) Patent Application Publication
(10) Pub. No.: US 2016/0307674 A1
(43) Pub. Date: Oct. 20, 2016

(54) VARISTOR PASTE, OPTOELECTRONIC COMPONENT, METHOD OF PRODUCING A VARISTOR PASTE AND METHOD OF PRODUCING A VARISTOR ELEMENT

(71) Applicant: OSRAM OPTO SEMICONDUCTORS GMBH, Regensburg (DE)

(72) Inventors: Klaus Hoehn, Forchheim (DE); Luca Haiberger, Regensburg (DE); Markus Wicke, Regensburg (DE)

(21) Appl. No.: 15/101,136

(22) PCT Filed: Dec. 2, 2014
(86) PCT No.: PCT/EP2014/076307

§ 371 Date: Jun. 2, 2016

(30) Foreign Application Priority Data
Dec. 4, 2013 (DE) 10 2013 224 899.7

(51) Int. Cl. H01C 7/10; H01L 27/02; H01L 25/16; H01C 17/065; H01L 33/62

(52) U.S. Cl. CPC H01C 7/1006; H01C 7/10; H01C 17/0652; H01C 17/06526; H01C 17/06586; H01L 33/62; H01L 25/167; H01L 27/0248

(57) ABSTRACT

A varistor paste includes a matrix material and particles embedded into the matrix material, wherein the matrix material without embedded particles has a viscosity of less than 0.8 Pa·s, and the embedded particles include varistor particles. An optoelectronic component includes an optoelectronic semiconductor chip and a varistor element connected in parallel with the optoelectronic semiconductor chip, wherein the varistor element includes a matrix material and particles embedded into the matrix material, the embedded particles include varistor particles, and the matrix material has a glass transition temperature of more than 130° C. A method of producing a varistor paste includes providing a matrix material having a viscosity of less than 0.8 Pa·s; and embedding particles into the matrix material to form a varistor paste, wherein the embedded particles include varistor particles.

### TECHNICAL FIELD

This disclosure relates to a varistor paste, an optoelectronic component, a method of producing a varistor paste, and a method of producing a varistor element.

### BACKGROUND

It is known that sensitive component parts of electronic and optoelectronic components have to be protected against damage by electrostatic discharges (ESD). One known possibility resides in the use of protective diodes connected in parallel with the component parts to be protected. However, the protective diodes require structural space available only to a limited extent in many cases. Moreover, the use of protective diodes is associated with increased costs and an increased mounting outlay.

DE 10 2012 207 772.3 describes varistor elements producible from a varistor paste and can be used instead of protective diodes in electronic components. The varistor paste comprises a matrix material having a viscosity of 0.8 Pa·s to 4 Pa·s.

### SUMMARY

We provide a varistor paste including a matrix material and particles embedded into the matrix material, wherein the matrix material without embedded particles has a viscosity of less than 0.8 Pa·s, and the embedded particles include varistor particles.

We also provide an optoelectronic component including an optoelectronic semiconductor chip and a varistor element connected in parallel with the optoelectronic semiconductor chip, wherein the varistor element includes a matrix material and particles embedded into the matrix material, the embedded particles include varistor particles, and the matrix material has a glass transition temperature of more than 130° C.

We further provide a method of producing a varistor paste including providing a matrix material having a viscosity of less than 0.8 Pa·s; and embedding particles into the matrix material to form a varistor paste, wherein the embedded particles include varistor particles.

We further yet provide a method of producing a varistor element including producing a varistor paste according to the method of producing a varistor paste including providing a matrix material having a viscosity of less than 0.8 Pa·s; and embedding particles into the matrix material to form a varistor paste, wherein the embedded particles include varistor particles, shaping a varistor element from the varistor paste; and curing the varistor element.

### BRIEF DESCRIPTION OF THE DRAWINGS

FIG. 1 shows a varistor paste.

FIG. 2 shows an optoelectronic component.

FIG. 3 shows a characteristic curve diagram of a varistor element.

### LIST OF REFERENCE SIGNS

100 Varistor paste
110 Matrix material
120 Embedded particles
130 Varistor particles
140 Electrically conductive particles
200 Optoelectronic component
210 Optoelectronic semiconductor chip
220 Top side
221 Upper electrical contact
230 Underside
231 Lower electrical contact
240 Carrier
250 First electrical contact pad
260 Second electrical contact pad
270 Connecting element
280 Varistor element
300 Characteristic curve diagram
310 Electrical voltage
320 Electric current
330 Current-voltage characteristic curve

### DETAILED DESCRIPTION

Our varistor paste comprises a matrix material and particles embedded into the matrix material. In this case, the matrix material without embedded particles has a viscosity of less than 0.8 Pa·s. The particles embedded into the matrix material comprise varistor particles. Advantageously, the low viscosity of the matrix material without embedded particles allows a high degree of filling of the particles of the varistor paste embedded into the matrix material. As a result, in varistor elements produced from the varistor paste, high response voltages can advantageously be achieved.

The matrix material without embedded particles may have a viscosity of less than 0.5 Pa·s. Particularly high degrees of filling of particles embedded into the matrix material are advantageously made possible as a result.

The matrix material may comprise a resin or a silicone. In this case, the matrix material can comprise in particular an epoxy resin, an acrylate, a polyurethane or a cyanate ester. Advantageously, these materials may have the desired low viscosity and enable later curing to produce a varistor element from the varistor paste. In LED components in which high temperatures of more than 150° C. and/or high brightnesses may occur in the package, silicones are preferable as a matrix material.

The matrix material may be a one-component matrix material. Preferably, the matrix material is a one-component epoxy resin mixture. Advantageously, the matrix material of the varistor paste may have a particularly good storage stability in this case.

90% by volume of the embedded particles may have a size of less than 20 μm. In this case, 50% by volume of the embedded particles have a size of less than 12 μm. Advantageously, the varistor paste thus has a fine-grain nature enabling production of varistor elements having very small spatial dimensions.

The embedded particles may make up at least 50% by weight of the varistor paste, preferably at least 60% by weight. Advantageously, varistor elements produced from the varistor paste may have a high response voltage as a result. The response voltage of varistor elements produced from the varistor paste may be above 10 V, for example.

The varistor paste may have a viscosity of less than 200 Pa·s. Preferably, the varistor paste has a viscosity of less than 100 Pa·s. Advantageously, the varistor paste can thus be processed further in a simple manner. By way of example, the varistor paste having a viscosity of less than 200 Pa·s, preferably less than 100 Pa·s, can be processed further to form varistor elements by a metering method or a printing method.

The embedded particles may comprise electrically conductive particles comprising Al, Cu, Ag, Au, Pd and/or some other metal, and/or electrically conductive particles comprising graphite, conductive carbon black, graphene and/or carbon nanotubes. Advantageously, electrically conductive particles embedded into the matrix material of the varistor paste increase an electrical conductivity of the varistor paste and an electrical conductivity of varistor elements produced from the varistor paste.

The electrically conductive particles may make up a proportion of less than 20% by weight of the embedded particles, preferably a proportion of less than 10% by weight. This advantageously ensures that varistor elements produced from the varistor paste have suitable varistor properties.

The varistor paste may have a thixotropic index of not more than 10, preferably a thixotropic index of not more than 6. In this case, the thixotropic index relates to a temperature of 23° C. Advantageously, a simple processability of the varistor paste is achieved by such a low thixotropic index.

An optoelectronic component comprises an optoelectronic semiconductor chip and a varistor element connected in parallel with the optoelectronic semiconductor chip. In this case, the varistor element comprises a matrix material and particles embedded into the matrix material. The embedded particles comprise varistor particles. The matrix material has a glass transition temperature of more than 130° C. The matrix material may comprise an epoxy resin, for example. Advantageously, the varistor element of this optoelectronic component protects the optoelectronic semiconductor chip against damage as a result of electrostatic discharges. In this case, the varistor element produced from a matrix material with embedded particles may advantageously have very small spatial dimensions. Moreover, the varistor element may advantageously be produced in a simple and cost-effective manner. The glass transition temperature of the matrix material of the varistor element of more than 130° C. advantageously prevents damage or destruction of the varistor element by temperatures that occur during operation of the optoelectronic component.

Our method of producing a varistor paste comprises steps of providing a matrix material having a viscosity of less than 0.8 Pa·s, and embedding particles into the matrix material to form a varistor paste, wherein the embedded particles comprise varistor particles. Advantageously, this method makes it possible to produce a varistor paste having a high degree of filling of the particles embedded into the matrix material of the varistor paste. This is made possible by the low viscosity of the matrix material of the varistor paste before the particles are embedded into the matrix material. As a result of a high degree of filling of the particles embedded into the matrix material, varistor elements having a high response voltage may be produced from the varistor paste obtainable via the method.

Our method of producing a varistor element comprises steps of producing a varistor paste according to a method of the type mentioned above, shaping a varistor element from the varistor paste, and curing the varistor element. Advantageously, the method enables a simple and cost-effective production of a varistor element. In this case, the varistor element can advantageously be formed with a very flexible geometry and with very small spatial dimensions.

As a result, the method enables integration of varistor elements into components with structural space available only to a limited extent.

The varistor element may be shaped by a metering method or by a printing method. In particular, the varistor element is shaped by needle metering, non-contact needle metering, stamp printing, pad printing, screen printing or stencil printing. Advantageously, these methods enable a simple and cost-effective shaping of the varistor element from the varistor paste. In this case, the method is advantageously suitable for mass production with a high degree of automation.

The varistor element may be cured by application of temperature or by irradiation with UV light, microwave radiation or electron radiation. When the varistor element is cured by application of temperature, the maximum hardening temperature is preferably less than 200° C., particularly preferably less than 180° C. Advantageously, the method can thus be carried out simultaneously for a multiplicity of varistor elements, which enables the method to be carried out cost-effectively.

The above-described properties, features and advantages and the way in which they are achieved will become clearer and more clearly understood in association with the following description of the examples which are explained in greater detail in association with the drawings.

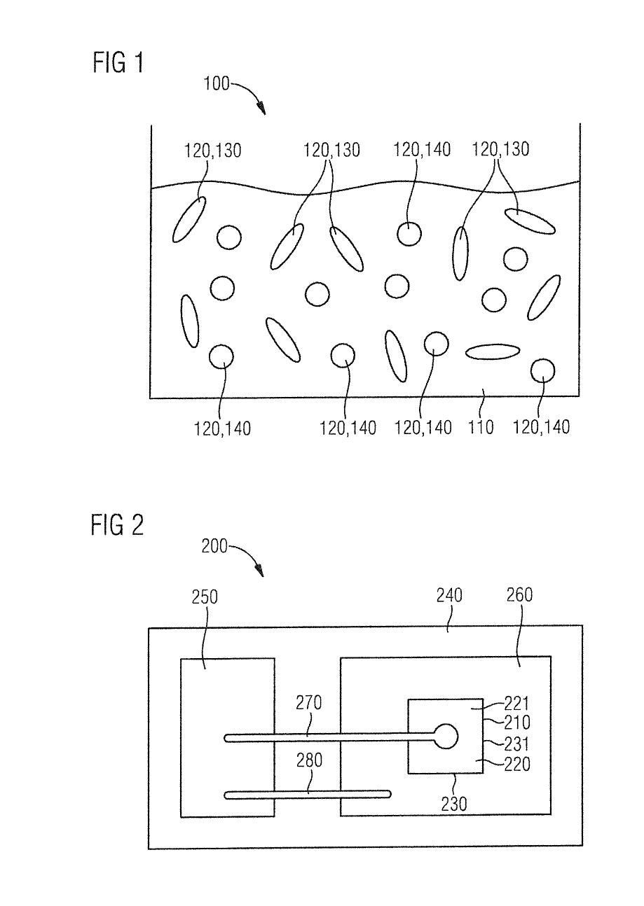

FIG. 1 shows a highly schematic illustration of a varistor paste 100. The varistor paste 100 can be used to produce varistor elements.

The varistor paste 100 is a viscous paste. The varistor paste 100 preferably has a viscosity of less than 200 Pa·S at a temperature of 23° C. Particularly preferably, the varistor paste 100 has a viscosity of less than 100 Pa·S at a temperature of 23° C. The thixotropic index of the varistor paste 100 at a temperature of 23° C. is preferably a maximum of 10, particularly preferably a maximum of 6. As a result, the rheology of the varistor paste 100 is adapted to an application by a metering method or a printing method.

The varistor paste 100 comprises a matrix material 110 and particles 120 embedded into the matrix material 110. In this case, the embedded particles 120 preferably make up at least 50% by weight of the varistor paste 100. Particularly preferably, the embedded particles 120 make up at least 60% by weight of the varistor paste 100. Advantageously, such a high degree of filling enables production of varistor elements from the varistor paste 100 having a high response voltage.

The matrix material 110 of the varistor paste 100 preferably comprises a resin or a silicone. By way of example, the matrix material 110 of the varistor paste 100 may comprise an epoxy resin, an acrylate, a polyurethane or a cyanate ester. Preferably, the matrix material 110 of the varistor paste 100 is a one-component matrix material, preferably comprising a one-component resin or silicone. Particularly preferably, the matrix material 110 of the varistor paste 100 comprises a one-component epoxy resin mixture. The matrix material 110 of the varistor paste 100 preferably has a storage stability at room temperature of at least six months.

The matrix material 110 of the varistor paste 100 without the embedded particles 120 has a viscosity of less than 0.8 Pa·s at a temperature of 23° C. Preferably, the matrix material 110 has a viscosity of less than 0.5 Pa·s at a temperature of 23° C. Such a low viscosity of the matrix material 110 of the varistor paste 100 makes it possible for the varistor paste 100, even in a filling with embedded particles 120 with a high degree of filling, still to have a viscosity that enables a simple processing of the varistor paste.

The particles 120 embedded into the matrix material 110 of the varistor paste 100 preferably have sizes of less than 20 μm. Particularly preferably, 90% by volume of the embedded particles 120 have a size of less than 20 μm (d90 value). Moreover, preferably 50% by volume of the embedded particles 120 have a size of less than 12 μm (d50 value). In this case, all the embedded particles 120 may have a size from a common narrow size interval. However, the embedded particles 120 may also be formed as a mixture of particles having sizes from different size intervals. The preferred low d90 and d50 values of the particles 120 embedded into the matrix material 110 of the varistor paste 100 advantageously enable varistor elements having very small spatial dimensions to be produced from the varistor paste 100.

The morphology of the particles 120 embedded into the matrix material 110 of the varistor paste 100 may be chosen in any desired manner. Particularly preferably, the particles 120 embedded into the matrix material 110 have lamina shapes. In this case, the dimensions of the embedded particles 120 in individual spatial directions may even be significantly smaller than the d90 and d50 values indicated. This advantageously makes it possible to produce from the varistor paste 100 varistor elements having spatial dimensions and structure widths which are smaller than the indicated preferred d90 and d50 values of the embedded particles 120.

The particles 120 embedded into the matrix material 110 of the varistor paste 100 comprise varistor particles 130. The varistor particles 130 have varistor properties or varistor behavior. The varistor particles 130 thus also impart varistor properties to the varistor paste 100 formed from the matrix material 110 and the particles 120 embedded into the matrix material 110 and to the varistor elements produced from the varistor paste 100.

The varistor particles 130 may comprise, for example, SiC or a metal oxide such as ZnO, bismuth oxide, chromium oxide, manganese oxide or cobalt oxide. The varistor particles 130 may also comprise a stoichiometric compound of a plurality of these or further materials. The varistor particles 130 may also be formed as a mixture of particles comprising different materials.

The varistor particles 130 may be present in doped or undoped form. By way of example, the varistor particles 130 may be doped with metals such as Sb, Co and Bi.

The varistor particles 130 may have any desired shapes. However, the varistor particles 130 are preferably formed in a lamina-shaped fashion or as flakes.

The particles 120 embedded into the matrix material 110 of the varistor paste 100 may also comprise electrically conductive particles 140 in addition to the varistor particles 130. The electrically conductive particles 140 may increase electrical conductivity of the varistor paste 100 and electrical conductivity of varistor elements produced from the varistor paste 100.

Preferably, the proportion of the electrically conductive particles 140 in the particles 120 embedded into the matrix material 110 of the varistor paste 100 is less than 20% by weight, particularly preferably less than 10% by weight. The electrically conductive particles 140 may also be completely omitted.

The electrically conductive particles 140 may comprise a metal such as Al, Cu, Ag, Au, Pd or some other metal. The electrically conductive particles 140 may also comprise conductive carbon, for example, graphite, conductive carbon black, graphene and/or carbon nanotubes.

FIG. 2 shows an exemplary and highly schematic plan view of an optoelectronic component 200. The optoelectronic component 200 emits electromagnetic radiation. The optoelectronic component 200 may be a light emitting diode component (LED component), for example.

The optoelectronic component 200 comprises an optoelectronic semiconductor chip 210. The optoelectronic semiconductor chip 210 emits electromagnetic radiation, for example visible light. The optoelectronic semiconductor chip 210 may be a light emitting diode chip (LED chip), for example.

The optoelectronic semiconductor chip 210 has a top side 220 and an underside 230 opposite the top side 220. An upper electrical contact 221 of the optoelectronic semiconductor chip 210 is formed at the top side 220 of the optoelectronic semiconductor chip 210. A lower electrical contact 231 of the optoelectronic semiconductor chip 210 is applied at the underside 230 of the optoelectronic semiconductor chip 210. Between the upper electrical contact 221 and the lower electrical contact 231 an electrical voltage can be applied to the optoelectronic semiconductor chip 210 to cause the optoelectronic semiconductor chip 210 to emit electromagnetic radiation.

The optoelectronic semiconductor chip 210 is arranged on a carrier 240 of the optoelectronic component 200. The carrier 240 comprises an electrically insulating material into which a first electrical contact pad 250 and a second electrical contact pad 260 are embedded. The first electrical contact pad 250 and the second electrical contact pad 260 may electrically conductively connect to electrical connection elements (not visible in FIG. 2) of the optoelectronic component 200 that electrically contact the optoelectronic component 200.

The optoelectronic semiconductor chip 210 is arranged on the second electrical contact pad 260 of the carrier 240 such that the underside 230 of the optoelectronic semiconductor chip 210 faces the second electrical contact pad 260 and the lower electrical contact 231 of the optoelectronic semiconductor chip 210 electrically conductively connects to the second electrical contact pad 260. By way of example, the optoelectronic semiconductor chip 210 may be fixed to the second electrical contact pad 260 of the carrier 240 via a soldering connection or by conductive adhesive, sintering adhesive or sintering paste. The upper electrical contact 221 of the optoelectronic semiconductor chip 210, the upper electrical contact being formed at the top side 220 of the optoelectronic semiconductor chip 210, electrically conductively connects to the first electrical contact pad 250 of the carrier 240 by a connecting element 270. The connecting element 270 may be formed as a bond wire, for example.

The described structure of the optoelectronic component 200 should be understood to be purely by way of example. The optoelectronic semiconductor chip 210, the arrangement of its contacts 221, 231, the carrier 240 and the type of connections between the electrical contacts 221, 231 and the contact pads 250, 260 of the carrier 240 may also be formed differently. Numerous possibilities are therefore known.

The optoelectronic component 200 comprises a varistor element 280, which extends between the first electrical contact pad 250 and the second electrical contact pad 260 of the carrier 240 and thus electrically connects in parallel with the optoelectronic semiconductor chip 210 of the optoelectronic component 200. The geometry and arrangement of the varistor element 280 may also be chosen differently than illustrated in the example in FIG. 2. All that is crucial is that the varistor element 280 electrically connects in parallel with the optoelectronic semiconductor chip 210.

The varistor element 280 may have a regular or irregular geometrical shape and structure. By way of example, the varistor element 280 may be formed as a square, rectangle, polygon, circle, ellipse or in linear form. The varistor element 280 may have, for example, structure widths of 50 μm to 150 μm and a thickness of 5 μm to 50 μm. The thickness of the varistor element 280 may be dimensioned, for example, perpendicular to the top side of the carrier 240 in the example illustrated in FIG. 2.

The varistor element 280 of the optoelectronic component 200 has been shaped from the varistor paste 100 shown in FIG. 1. The varistor element 280 has been cured after the shaping of the varistor element 280 from the varistor paste 100.

Shaping of the varistor element 280 from the varistor paste 100 may have been performed by an arbitrary established application method. By way of example, shaping of the varistor element 280 from the varistor paste 100 may have been performed by a metering method or a printing method. In particular, shaping of the varistor element 280 from the varistor paste 100 may have been performed by needle metering (dispensing), non-contact needle metering (jetting), stamp printing, pad printing, screen printing or stencil printing.

Curing the varistor element 280 has been performed by a hardening method. By way of example, curing the varistor element 280 may be performed by application of temperature or by irradiation with UV light, microwave radiation or electron radiation. In curing the varistor element 280 by application of temperature, the hardening temperature preferably has a maximum of 200° C., particularly preferably a maximum of 180° C. As a result of the curing of the varistor element 280, the varistor paste 100 is converted into a varistor composite material.

The varistor composite material of the varistor element 280 preferably has a glass transition temperature of more than 130° C. This ensures that the varistor element 280 of the optoelectronic component 200 is not damaged by operating temperatures occurring during operation of the optoelectronic component 200. In particular, the varistor element 280 is not damaged by waste heat of the optoelectronic semiconductor chip 210 arising during operation of the optoelectronic component 200. The optoelectronic semiconductor chip 210 of the optoelectronic component 200 may assume a temperature of up to 110° C., for example, during operation of the optoelectronic component 200.

The varistor element 280 of the optoelectronic component 200 protects the optoelectronic semiconductor chip 210 of the optoelectronic component 200 against damage as a result of electrostatic discharges. If an electrical voltage whose absolute value does not exceed a permissible rated voltage of the optoelectronic semiconductor chip 210 is present between the first electrical contact pad 250 and the second electrical contact pad 260 of the carrier 240 of the optoelectronic component 200, then the varistor element 280 has a high electrical resistance that ensures that a current flow takes place substantially only through the optoelectronic semiconductor chip 210 and not through the varistor element 280.

However, if an electrical voltage whose absolute value exceeds a permissible rated voltage of the optoelectronic semiconductor chip 210 is present between the first electrical contact pad 250 and the second electrical contact pad 260, then the varistor element 280 has a low electrical resistance having the effect that a current flow takes place substantially via the varistor element 280 and not via the optoelectronic semiconductor chip 210. Damage to the optoelectronic semiconductor chip 210 is thus prevented.

The permissible rated voltage of the optoelectronic semiconductor chip 210 may be 10 V to 100 V, for example. The response voltage of the varistor element 280, starting from which the electrical resistance of the varistor element 280 falls abruptly, is above the permissible rated voltage of the optoelectronic semiconductor chip 210.

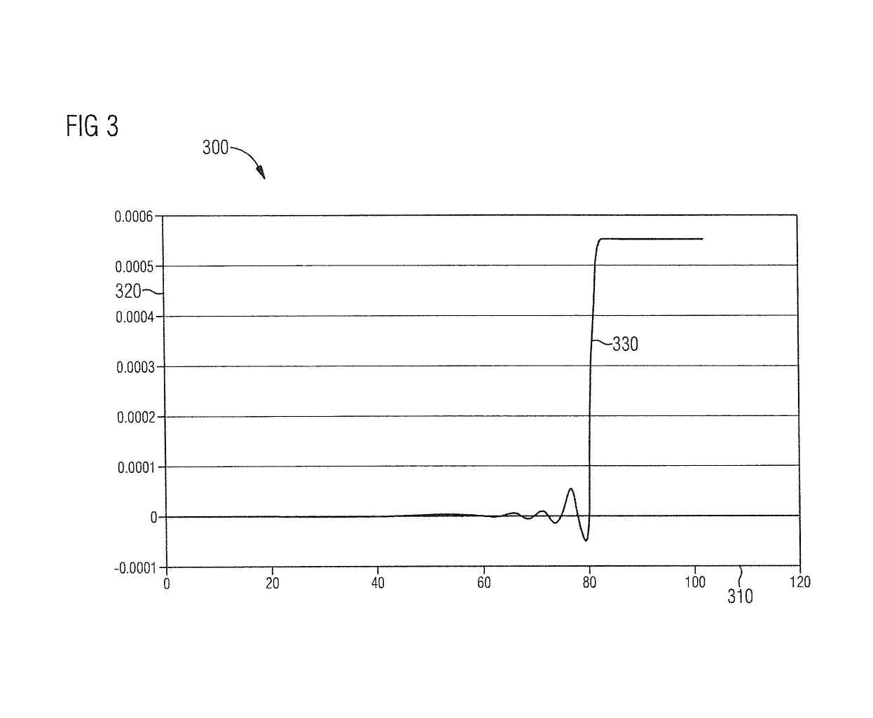

FIG. 3 shows a schematic example of a curve diagram 300 of the varistor element 280. An electrical voltage 310 applied to the varistor element 280 is plotted on a horizontal axis of the characteristic curve diagram 300. A current intensity 320 of an electric current flowing through the varistor element 280 is plotted on a vertical axis of the characteristic curve diagram 300.

The characteristic curve diagram 300 illustrates an exemplary current-voltage characteristic curve 330 of the varistor element 280 when the response voltage of the varistor element 280 is approximately 80 V. If the value of the electrical voltage 310 present across the varistor element 280 is below the response voltage of the varistor element 280, then the electrical resistance of the varistor element 280 is high and substantially no electric current 320 flows through the varistor element 280. If the value of the voltage 310 applied to the varistor element 280 exceeds the response voltage of the varistor element 280, then the electrical resistance of the varistor element 280 falls abruptly and a non-vanishing electric current 320 may flow through the varistor element 280.

Our pastes, components and methods have been illustrated and described in greater detail on the basis of the preferred examples. Nevertheless, this disclosure is not restricted to the examples disclosed. Rather, other variations can be derived there from by those skilled in the art, without departing from the scope of protection of this disclosure.

This application claims priority of DE 10 2013 224 899.7, the subject matter of which is incorporated herein by reference.

1-15. (canceled)

16. A varistor paste comprising a matrix material and particles embedded into the matrix material,
wherein the matrix material without embedded particles has a viscosity of less than 0.8 Pa·s, and
the embedded particles comprise varistor particles.

17. The varistor paste as claimed in claim 16, wherein the matrix material without embedded particles has a viscosity of less than 0.5 Pa·s.

18. The varistor paste as claimed in claim 16, wherein the matrix material comprises a resin, a silicone, an epoxy resin, an acrylate, a polyurethane or a cyanate ester.

19. The varistor paste as claimed in claim 16, wherein the matrix material is a one-component matrix material.

20. The varistor paste as claimed in claim 16,
wherein 90% by volume of the embedded particles have a size of less than 20 μm, and 50% by volume of the embedded particles have a size of less than 12 μm.

21. The varistor paste as claimed in claim 16, wherein the embedded particles make up at least 50% by weight of the varistor paste.

22. The varistor paste as claimed in claim 16, wherein the varistor paste has a viscosity of less than 200 Pa·s.

23. The varistor paste as claimed in claim 16, wherein the embedded particles at least comprise one of electrically conductive particles comprising Al, Cu, Ag, Au, Pd, other metals, or electrically conductive particles comprising graphite, conductive carbon black, graphene or carbon nanotubes.

24. The varistor paste as claimed in claim 23, wherein the electrically conductive particles are less than 20% by weight of the embedded particles.

25. The varistor paste as claimed in claim 16, wherein the varistor paste has a thixotropic index of not more than 10.

26. An optoelectronic component comprising an optoelectronic semiconductor chip and a varistor element connected in parallel with the optoelectronic semiconductor chip,
wherein the varistor element comprises a matrix material and particles embedded into the matrix material,
the embedded particles comprise varistor particles, and
the matrix material has a glass transition temperature of more than 130° C.

27. A method of producing a varistor paste comprising:
providing a matrix material having a viscosity of less than 0.8 Pa·s; and
embedding particles into the matrix material to form a varistor paste,
wherein the embedded particles comprise varistor particles.

28. A method of producing a varistor element comprising:
producing a varistor paste according to the method as claimed in claim 27;
shaping a varistor element from the varistor paste; and
curing the varistor element.

29. The method as claimed in claim 28, wherein the varistor element is shaped by a needle metering, non-contact needle metering, stamp printing, pad printing, screen printing or stencil printing.

30. The method as claimed in claim 28, wherein the varistor element is cured by application of temperature or irradiation with UV light, microwave radiation or electron radiation.
